(19) United States
(12) Patent Application Publication
(10) Pub. No.: US 2015/0241932 A1
(43) Pub. Date: Aug. 27, 2015

(54) STORING DEVICE

(71) Applicant: Power Quotient International Co., Ltd., New Taipei City (TW)

(72) Inventors: Ya Fen Chen, New Taipei City (TW); Shu Chin Liang, New Taipei City (TW); Ying Chih Chang, New Taipei City (TW); Chia Hsin Tsai, New Taipei City (TW)

(73) Assignee: Power Quotient International Co., Ltd., New Taipei City (TW)

(21) Appl. No.: 14/247,299

(22) Filed: Apr. 8, 2014

(30) Foreign Application Priority Data
Feb. 21, 2014 (TW) 103203067

(51) Int. Cl. G06F 1/18; H05K 5/02

(52) U.S. Cl. CPC G06F 1/182; H05K 5/0278; H05K 5/0243

(57) ABSTRACT

A storing device includes a storing unit, a first cap, a second cap and a hollow housing. The storing unit has a storing module and a processing module which are disposed in the storing unit. The storing unit includes a first inserting port and a second inserting port which are oppositely positioned in two opposite sides of the storing unit. The first cap removably covers the first inserting port of the storing unit. The second cap removably covers the second inserting port of the storing unit. The hollow housing sheathes the storing unit therein and is located between the first cap and the second cap. The first inserting port and the second inserting port oppositely project beyond two end faces of the hollow housing. The hollow housing has a first connecting arm connected to the first cap and a second connecting arm connected to the second cap.

### BACKGROUND OF THE INVENTION

1. Field of the Invention

The present invention relates to a device, and more particularly to a storing device.

2. The Related Art

Nowadays, with the progress of society, storing devices have become indispensable tools in people's daily life to store or transfer data. A traditional storing device usually has a storing unit with an inserting port such as USB(Universal Serial Bus) port, a decorative shell sheathing the storing unit therein, and a cap covering the inserting port. In use, people need to take off the cap and then insert the inserting port into the mating equipment to transfer the data or document between the storing device and the mating equipment.

However, the cap is easily lost because of no connecting portion between the cap and the decorative shell, so the inserting port of the storing device can't be protected by the cap greatly.

### SUMMARY OF THE INVENTION

Accordingly, an object of the present invention is to provide a storing device including a storing unit, a first cap, a second cap and a hollow housing. The storing unit has a storing module and a processing module which are disposed in the storing unit. The storing unit includes a first inserting port and a second inserting port which are oppositely positioned in two opposite sides of the storing unit. The first cap removably covers the first inserting port of the storing unit. The second cap removably covers the second inserting port of the storing unit. The hollow housing sheathes the storing unit therein and is located between the first cap and the second cap. The first inserting port and the second inserting port oppositely project beyond two end faces of the hollow housing. The hollow housing has a first connecting arm connected to the first cap and a second connecting arm connected to the second cap.

As described above, the embodiment of the invention of the storing device includes the hollow housing sheathing the storing unit therein, and the hollow housing further has the first connecting arm connected to the first cap and the second connecting arm connected to the second cap. When open the first cap or the second cap to use the first inserting port or the second inserting port, the first cap and the second cap don't lose away because of the first connecting arm connecting between the first cap and the hollow housing and the second connecting arm connecting between the second cap and the hollow housing.

### BRIEF DESCRIPTION OF THE DRAWINGS

The present invention will be apparent to those skilled in the art by reading the following description thereof, with reference to the attached drawings, in which:

FIG. 1 is an assembled, perspective view of a storing device in accordance with an embodiment of the present invention;

FIG. 2 is an assembled, perspective view of the storing device opening a first cap shown in FIG. 1;

FIG. 3 is an exploded, perspective view of the storing device shown in FIG. 1; and

FIG. 4 is an assembled, perspective view of the storing device opening a second cap shown in FIG. 1.

### DETAILED DESCRIPTION OF THE EMBODIMENT

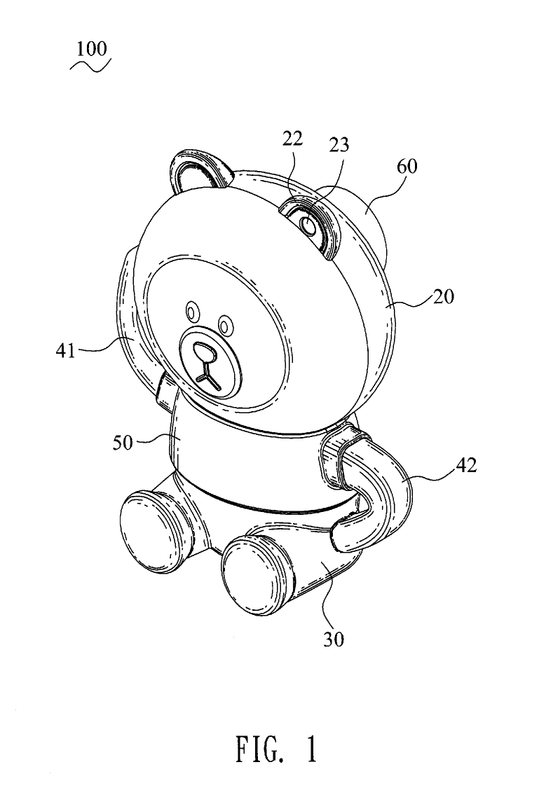

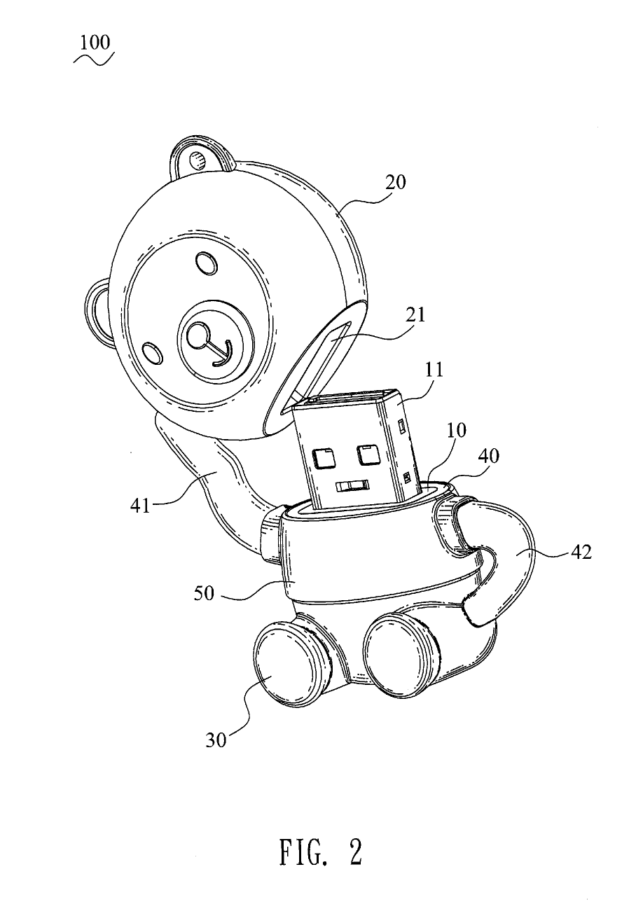

With reference to FIG. 1 and FIG. 2, an embodiment of the present invention is shown as a storing device 100 which includes a storing unit 10, a first cap 20, a second cap 30, a hollow housing 40, a decorative housing 50 and a sucking disk 60.

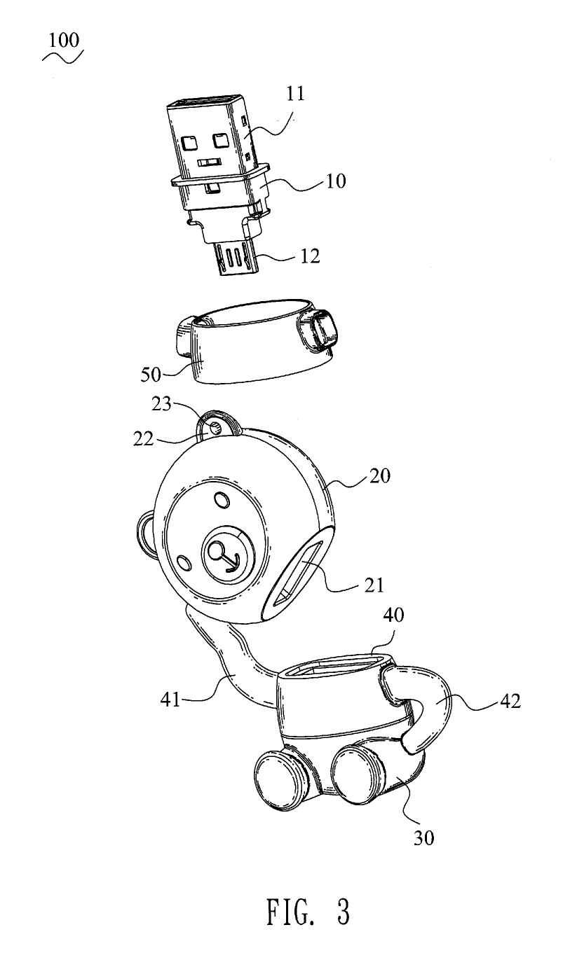

Referring to FIG. 3, the storing unit 10 has a storing module (not shown) and a processing module (not shown) which are disposed in the storing unit 10. The storing unit 10 includes a first inserting port 11 and a second inserting port 12 which are oppositely positioned in two opposite sides of the storing unit 10.

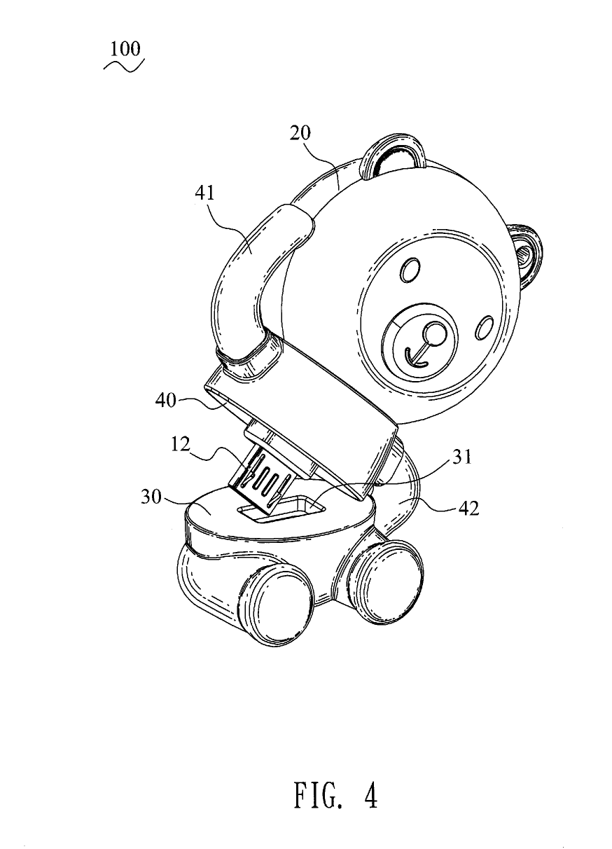

Referring to FIG. 1, FIG. 2, FIG. 3 and FIG. 4, the first cap 20 removably covers the first inserting port 11 of the storing unit 10 and the second cap 30 removably covers the second inserting port 12 of the storing unit 10. The hollow housing 40 sheathes the storing unit 10 therein and is located between the first cap 20 and the second cap 30. The first inserting port 11 and the second inserting port 12 oppositely project beyond two end faces of the hollow housing 40. The hollow housing 40 has a first connecting arm 41 connected to the first cap 20 and a second connecting arm 42 connected to the second cap 30.

In detail, the first connecting arm 41 and the second connecting arm 42 are made of elastic plastic material, and integral with the first cap 20, the second cap 30 and the hollow housing 40 by injection molding. The first connecting arm 41 and the second connecting arm 42 are positioned at two opposite side faces of the hollow housing 40. In this embodiment, the elastic plastic material is an environmentally-friendly silica gel.

Referring to FIG. 1, FIG. 2 and FIG. 4, a substantial middle of the first cap 20 defines a first receiving slot 21 penetrating through the face thereof against one end face of the hollow housing 40 and corresponding to the first inserting port 11 of the storing unit 10, and a substantial middle of the second cap 30 defines a second receiving slot 31 penetrating through the face thereof against the other end face of the hollow housing 40 and corresponding to the second inserting port 12 of the storing unit 10. The first inserting port 11 of the storing unit 10 is inserted in the first receiving slot 21 of the first cap 20. The second inserting port 12 of the storing unit 10 is inserted in the second receiving slot 31 of the second cap 30.

Referring to FIGS. 1 and 2, the decorative housing 50 is worn around the hollow housing 40. The sucking disk 60 is positioned in the rear face of the first cap 20.

Referring to FIGS. 1 to 4, in this embodiment, the storing device 100 is designed to show a teddy bear shape. In detail, the hollow housing 40 is designed as an upper body of the teddy bear, and the first connecting arm 41 and the second connecting arm 42 are designed as two arms of the teddy bear. The first cap 20 is designed as a head of the teddy bear, and has two ears 22 protruded at two sides of an end thereof far away from the hollow housing 40. One of the ears 22 is opened with a through hole 23 for hanging decorations. The second cap 30 is designed as a lower body of the teddy bear which appears sitting posture. The decorative housing 50 is designed as a clothing of the teddy bear. In assembly, the first cap 20, the second cap 30, the hollow housing 40 and the decorative housing 50 constitute a full body of the teddy bear to make the storing device 100 look beautiful.

As described above, the embodiment of the invention of the storing device 100 includes the hollow housing 40 sheathing the storing unit 10 therein, and the hollow housing 40 further has the first connecting arm 41 connected to the first cap 20 and the second connecting arm 42 connected to the second cap 30. When open the first cap 20 or the second cap 30 to use the first inserting port 11 or the second inserting port 12, the first cap 20 and the second cap 30 don't lose away because of the first connecting arm 41 connecting between the first cap 20 and the hollow housing 40 and the second connecting arm 42 connecting between the second cap 30 and the hollow housing 40.

What is claimed is:

1. A storing device, comprising:
a storing unit having a storing module and a processing module which are disposed in the storing unit, the storing unit including a first inserting port and a second inserting port which are oppositely positioned in two opposite sides of the storing unit;
a first cap removably covering the first inserting port of the storing unit;
a second cap removably covering the second inserting port of the storing unit; and
a hollow housing sheathing the storing unit therein and located between the first cap and the second cap, the first inserting port and the second inserting port oppositely projecting beyond two end faces of the hollow housing, the hollow housing having a first connecting arm connected to the first cap and a second connecting arm connected to the second cap.

2. The storing device as claimed in claim 1, wherein a substantial middle of the first cap defines a first receiving slot penetrating through the face thereof against one end face of the hollow housing and corresponding to the first inserting port of the storing unit, a substantial middle of the second cap defines a second receiving slot penetrating through the face thereof against the other end face of the hollow housing and corresponding to the second inserting port of the storing unit, the first inserting port is inserted in the first receiving slot and the second inserting port is inserted in the second receiving slot.

3. The storing device as claimed in claim 1, wherein the first connecting arm and the second connecting arm are positioned at two opposite side faces of the hollow housing.

4. The storing device as claimed in claim 1, wherein the first connecting arm and the second connecting arm are made of elastic plastic material, and integral with the first cap, the second cap and the hollow housing by injection molding.

5. The storing device as claimed in claim 4, wherein the elastic plastic material is an environmentally-friendly silica gel.

6. The storing device as claimed in claim 1, further comprising a decorative housing which is worn around the hollow housing.

7. The storing device as claimed in claim 1, further comprising a sucking disk positioned in the rear face of the first cap.

8. The storing device as claimed in claim 1, wherein the first cap has two ears protruded at two sides of an end thereof far away from the hollow housing, and one of the ears is opened with a through hole.
